(19) United States
(12) Patent Application Publication
(10) Pub. No.: US 2019/0292653 A1
(43) Pub. Date: Sep. 26, 2019

(54) APPARATUS AND METHOD FOR TRANSPORTATION OF A DEPOSITION SOURCE

(71) Applicants: Stefan BANGERT, Steinau (DE); Oliver HEIMEL, Wabem (DE); Dieter HAAS, San Jose, CA (US); Tommaso VERCESI, Aschaffenburg (DE); Applied Materials, Inc., Santa Clara, CA (US)

(72) Inventors: Stefan BANGERT, Steinau (DE); Oliver HEIMEL, Wabern (DE); Dieter HAAS, San Jose, CA (US); Tommaso VERCESI, Aschaffenburg (DE)

(21) Appl. No.: 16/302,593

(22) PCT Filed: May 18, 2016
(86) PCT No.: PCT/EP2016/061141

§ 371 Date: Nov. 16, 2018

(51) Int. Cl. C23C 14/24; C23C 14/12; C23C 14/56

(52) U.S. Cl. CPC C23C 14/24; C23C 14/56; C23C 14/12

(57) ABSTRACT

An apparatus for contactless transportation of a deposition source is provided. The apparatus includes a deposition source assembly. The deposition source assembly includes the deposition source. The deposition source assembly includes a first active magnetic unit. The apparatus includes a guiding structure extending in a source transportation direction. The deposition source assembly is movable along the guiding structure. The first active magnetic unit and the guiding structure are configured for providing a first magnetic levitation force for levitating the deposition source assembly.

### FIELD

Embodiments of the present disclosure relate to apparatuses and methods for 10 transportation of deposition sources, more specifically deposition sources for layer deposition on large area substrates.

### BACKGROUND

Techniques for layer deposition on a substrate include, for example, organic 15 evaporation using organic light-emitting diodes (OLEDs), sputtering deposition and chemical vapor deposition (CVD). A deposition process can be used to deposit a material layer on the substrate, such as a layer of an insulating material.

For example, coating processes may be considered for large area substrates, e.g. in display manufacturing technology. For coating a large area substrate, a movable 20 deposition source may be provided. The deposition source can be transported along the substrate while emitting material to be deposited on the substrate. Accordingly, a surface of the substrate may be coated by the moving deposition source.

A continuing issue in layer formation processes is the ever-increasing demand for higher uniformity and purity of the deposited layers. In this respect, many challenges arise 25 in coating processes where the deposition source is transported over a distance during the deposition process.

In view of the above, there is a need for apparatuses which can provide for an improved control of the transportation of a deposition source during the layer deposition process.

### SUMMARY

According to an embodiment, an apparatus for contactless transportation of a deposition source is provided. The apparatus includes a deposition source assembly. The deposition source assembly includes the deposition source. The deposition source assembly includes a first active magnetic unit. The apparatus includes a guiding structure extending in a source transportation direction. The deposition source assembly is movable along the guiding structure. The first active magnetic unit and the guiding structure are configured for providing a first magnetic levitation force for levitating the deposition source assembly.

According to an embodiment, an apparatus for contactless levitation of a deposition source is provided. The apparatus comprises a deposition source assembly with a first plane including a first rotation axis of the deposition source assembly. The deposition source assembly comprises the deposition source. The deposition source assembly comprises a first active magnetic unit arranged at a first side of the first plane. The deposition source assembly comprises a second active magnetic unit arranged at a second side of the first plane. The first active magnetic unit and the second active magnetic unit are configured for magnetically levitating the deposition source assembly. The first active magnetic unit and the second active magnetic unit are configured for rotating the deposition source around the first rotation axis for alignment of the deposition source.

According to an embodiment, which can be combined with other embodiments described herein, a method for contactlessly aligning a deposition source is provided. The method includes generating an adjustable magnetic field to levitate the deposition source. The method includes controlling the adjustable magnetic field to align the deposition source.

According to an embodiment, which can be combined with other embodiments described herein, a method for contactlessly aligning a deposition source is provided. The method includes providing a first magnetic levitation force and a second magnetic levitation force to levitate the deposition source. The first magnetic levitation force is distanced from the second magnetic levitation force. The method includes controlling at least one of the first magnetic levitation force and the second magnetic levitation force to align the deposition source.

### BRIEF DESCRIPTION OF THE DRAWINGS

So that the manner in which the above recited features of the present disclosure can be understood in detail, a more particular description of the disclosure, briefly summarized above, may be had by reference to embodiments. The accompanying drawings relate to embodiments of the disclosure and are described in the following:

FIG. 1 shows a schematic side view of an apparatus for contactless levitation of a deposition source according to embodiments described herein;

FIGS. 2-4 show a schematic front view of an apparatus for contactless levitation of a deposition source according to embodiments described herein;

FIGS. 5-8 show schematic views of apparatuses for contactless levitation according to embodiments described herein;

FIGS. 9a-d show schematic views of a source support with magnetic units according to embodiments described herein;

FIGS. 10-11 show schematic views of deposition sources according to embodiments described herein; and

FIGS. 12-13 show flow diagrams illustrating methods according to embodiments described herein.

### DETAILED DESCRIPTION OF EMBODIMENTS

Reference will now be made in detail to the various embodiments of the disclosure, one or more examples of which are illustrated in the figures. Within the following description of the drawings, the same reference numbers refer to same components. Generally, only the differences with respect to individual embodiments are described. Each example is provided by way of explanation of the disclosure and is not meant as a limitation of the disclosure. Further, features illustrated or described as part of one embodiment can be used on, or in conjunction with, other embodiments to yield yet a further embodiment. It is intended that the description includes such modifications and variations.

Embodiments described herein relate to contactless levitation, transportation and/or alignment of a deposition source assembly or deposition source. The term “contactless” as used throughout the present disclosure can be understood in the sense that a weight of the deposition source assembly is not held by a mechanical contact or mechanical forces, but is held by a magnetic force. Specifically, the deposition source assembly is held in a levitating or floating state using magnetic forces instead of mechanical forces. As an example, the apparatus described herein may have no mechanical means, such as a mechanical rail, supporting the weight of the deposition source assembly. In some implementations, there can be no mechanical contact between the deposition source assembly and the rest of the apparatus at all during movement of the deposition source assembly or deposition source past a substrate.

The contactless levitation, transportation and/or alignment of the deposition source according to embodiments described herein is beneficial in that no particles are generated due to a mechanical contact between the deposition source assembly and sections of the apparatus, such as mechanical rails, during the transport or alignment of the deposition source. Accordingly, embodiments described herein provide for an improved purity and uniformity of the layers deposited on the substrate, in particular since a particle generation is minimized when using the contactless levitation, transportation and/or alignment.

A further advantage, as compared to mechanical means for guiding the deposition source, is that embodiments described herein do not suffer from friction affecting the linearity of the movement of the deposition source along the substrate to be coated. The contactless transportation of the deposition source allows for a frictionless movement of the deposition source, wherein a target distance between the deposition source and the substrate can be controlled and maintained with high precision and speed.

Yet further, the levitation allows for fast acceleration or deceleration of the source speed and/or fine adjustment of the source speed. Embodiments of the present disclosure provide an improved layer uniformity, which is sensitive to several factors, such as e.g. variations in the distance between the deposition source and the substrate, or variations in the speed at which the deposition source is moved along the substrate while emitting material. Small deviations from a target distance or speed may affect the uniformity of the deposited layer. Accordingly, embodiments described herein provide an improved layer uniformity.

Further, the material of mechanical rails typically suffers from deformations which may be caused by evacuation of a chamber, by temperature, usage, wear, or the like. Such deformations affect the distance between the deposition source and the substrate, and hence affect the uniformity of the deposited layers. In contrast, embodiments described herein allow for a compensation of any potential deformations present in e.g. the guiding structure described herein. In view of the contactless manner in which the deposition source is levitated and transported, embodiments described herein allow for a contactless alignment, i.e. positioning relative to the substrate, of the deposition source. Accordingly, an improved layer uniformity can be provided. Particularly for an apparatus, wherein a deposition source is configured for deposition in a first substrate receiving area and a second, different substrate receiving area and alignment, i.e. a positioning of the deposition source can improved the uniformity. According to some embodiments described herein, which can be combined with other embodiments described herein, the alignment or the positioning relative to the substrate is conducted while the deposition source is moved past the substrate for depositing material on the substrate. According to yet further embodiments, which can be combined with other embodiments described herein, the alignment or the positioning relative to the substrate is conducted for a first substrate in a first position and a second substrate in a second position, wherein the second position opposes the first position, i.e. wherein the deposition source can move between the first position and the second position.

For example, embodiments described herein allow for a contactless translation of a deposition source assembly along one, two or three spatial directions for aligning the deposition source. The alignment of the deposition source may be an alignment, e.g. translational or rotational, with respect to a substrate to be coated, e.g. in order to position the deposition source at a target distance from the substrate. According to embodiments, which can be combined with other embodiments described herein, the apparatus is configured for a contactless translation of the deposition source assembly along a vertical direction, e.g. the y-direction, and/or along one or more transversal directions, e.g. the x-direction and z-direction. An alignment range for the deposition source may be 2 mm or below, more particularly 1 mm or below.

Embodiments described herein allow for a contactless rotation of the deposition source assembly with respect to one, two or three rotation axes for angularly aligning the deposition source. The alignment of the deposition source may e.g. involve positioning the deposition source in a target vertical orientation with respect to the substrate. According to embodiments, which can be combined with other embodiments described herein, the apparatus is configured for contactless rotation of the deposition source assembly around a first rotation axis, a second rotation axis and/or a third rotation axis. The first rotation axis may extend in a transversal direction, e.g. the x-direction or source transportation direction. The second rotation axis may extend in a transversal direction, e.g. the z-direction. The third rotation axis may extend in a vertical direction, e.g. the y-direction. Rotation of the deposition source assembly with respect to any rotation axis may be provided within an angle of 2° or below, e.g. from 0.1 degrees to 2 degrees or from 0.5 degrees to 2 degrees.

In the present disclosure, the terminology of “substantially parallel” directions may include directions which make a small angle of up to 10 degrees with each other, or even up to 15 degrees. Further, the terminology of “substantially perpendicular” directions may include directions which make an angle of less than 90 degrees with each other, e.g. at least 80 degrees or at least 75 degrees. Similar considerations apply to the notions of substantially parallel or perpendicular axes, planes, areas or the like.

Some embodiments described herein involve the notion of a “vertical direction”. A vertical direction is considered to be a direction substantially parallel to the direction along which the force of gravity extends. A vertical direction may deviate from exact verticality (the latter being defined by the gravitational force) by an angle of, e.g., up to 15 degrees. For example, the y-direction described herein (indicated with “Y” in the figures) is a vertical direction. In particular, the y-direction shown in the figures defines the direction of gravity.

The apparatuses described herein can be used for vertical substrate processing. Therein, the substrate is vertically oriented during processing of the substrate, i.e. the substrate is arranged parallel to a vertical direction as described herein, i.e. allowing possible deviations from exact verticality. A small deviation from exact verticality of the substrate orientation can be provided, for example, because a substrate support with such a deviation might result in a more stable substrate position or a reduced particle adherence on a substrate surface. An essentially vertical substrate may have a deviation of +−15° or below from the vertical orientation.

Embodiments described herein may further involve the notion of a “transversal direction”. A transversal direction is to be understood to distinguish over a vertical direction. A transversal direction may be perpendicular or substantially perpendicular to the exact vertical direction defined by gravity. For example, the x-direction and the z-direction described herein (indicated with “X” and “Z” in the figures) are transversal directions. In particular, the x-direction and the z-direction shown in the figures are perpendicular to the y-direction (and to each other). In further examples, transversal forces or opposing forces, as described herein, are considered to extend along transversal directions.

The embodiments described herein can be utilized for coating large area substrates, e.g., for display manufacturing. The substrates or substrate receiving areas for which the apparatuses and methods described herein are provided can be large area substrates. For example, a large area substrate or carrier can be GEN 4.5, which corresponds to about 0.67 m² substrates (0.73×0.92 m), GEN 5, which corresponds to about 1.4 m² substrates (1.1 m×1.3 m), GEN 7.5, which corresponds to about 4.29 m² substrates (1.95 m×2.2 m), GEN 8.5, which corresponds to about 5.7 m² substrates (2.2 m×2.5 m), or even GEN 10, which corresponds to about 8.7 m² substrates (2.85 m×3.05 m). Even larger generations such as GEN 11 and GEN 12 and corresponding substrate areas can similarly be implemented.

The term “substrate” as used herein may particularly embrace substantially inflexible substrates, e.g., a wafer, slices of transparent crystal such as sapphire or the like, or a glass plate. However, the present disclosure is not limited thereto and the term “substrate” may also embrace flexible substrates such as a web or a foil. The term “substantially inflexible” is understood to distinguish over “flexible”. Specifically, a substantially inflexible substrate can have a certain degree of flexibility, e.g. a glass plate having a thickness of 0.5 mm or below, wherein the flexibility of the substantially inflexible substrate is small in comparison to the flexible substrates.

A substrate may be made of any material suitable for material deposition. For instance, the substrate may be made of a material selected from the group consisting of glass (for instance soda-lime glass, borosilicate glass etc.), metal, polymer, ceramic, compound materials, carbon fiber materials or any other material or combination of materials which can be coated by a deposition process.

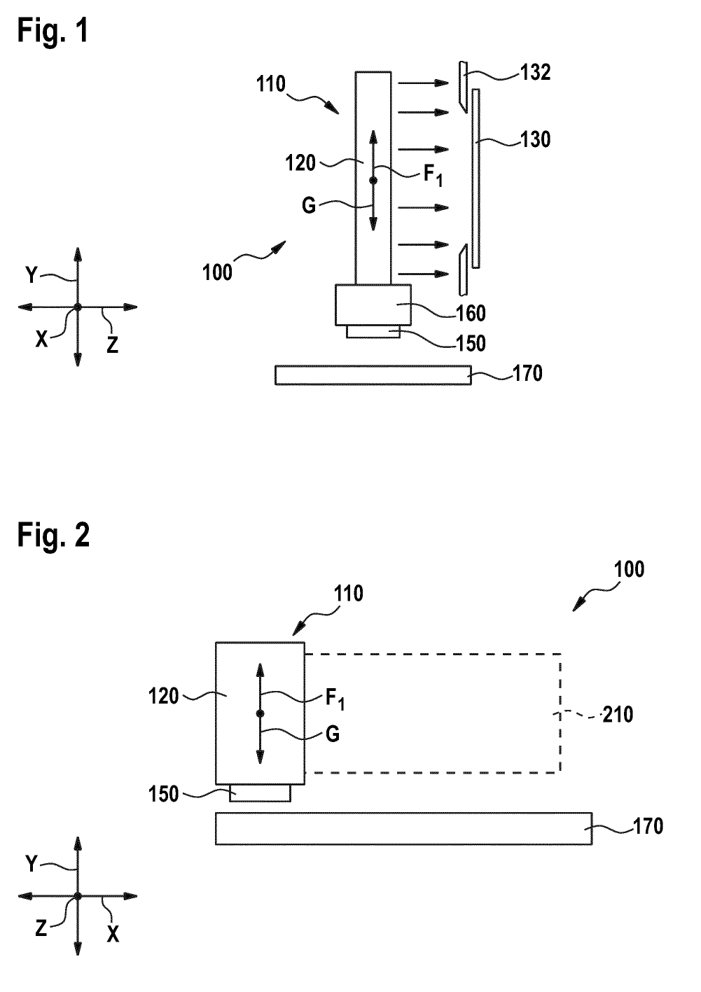

As illustrated in FIG. 1, according to an embodiment, an apparatus 100 for contactless transportation of a deposition source 120 is provided. The apparatus includes a deposition source assembly 110. The deposition source assembly 110 includes the deposition source 120. The deposition source assembly 110 includes a first active magnetic unit 150. The apparatus includes a guiding structure 170 extending in a source transportation direction. The deposition source assembly 110 is movable along the guiding structure 170. The first active magnetic unit 150 and the guiding structure 170 are configured for providing a first magnetic levitation force for levitating the deposition source assembly 110. The means for levitating as described herein are means for providing a contactless force to levitate e.g. a deposition source assembly.

FIG. 1 illustrates an operational state of an apparatus 100 according to an embodiment, which can be combined with other embodiments described herein. The apparatus may be configured for layer deposition on a substrate 130.

According to embodiments, which can be combined with other embodiments described herein, the apparatus 100 may be arranged in a processing chamber. The processing chamber may be a vacuum chamber or a vacuum deposition chamber. The term “vacuum”, as used herein, can be understood in the sense of a technical vacuum having a vacuum pressure of less than, for example, 10 mbar. The apparatus 100 can include one or more vacuum pumps, such as turbo pumps and/or cryo-pumps, connected to the vacuum chamber for generation of the vacuum inside the vacuum chamber.

FIG. 1 shows a side view of the apparatus 100. The apparatus 100 includes a deposition source assembly 110. The deposition source assembly 110 includes a deposition source 120. For example, the deposition source 120 may be an evaporation source or a sputter source. As indicated by the arrows in FIG. 1, the deposition source 120 is adapted for emitting material for deposition of the material on the substrate 130.

According to embodiments of the present disclosure, the deposition source assembly may include one or more point sources. Alternatively, as shown in FIG. 1, one or more line sources, e.g. sources extending for example in y-direction in FIG. 1, can be included in the deposition source assembly 110. A line source has the advantage that a source levitation as described herein may be combined with a transversal movement of the source, e.g. in x-direction in FIG. 1, in order to deposit a uniform material layer, e.g. in an x-y-plane in FIG. 1.

Depositing the material on the substrate allows forming thin layers of material on the substrate 130, e.g. by evaporation or sputtering. As shown in FIG. 1, a mask 132 may be arranged between the substrate 130 and the deposition source 120. The mask 132 is provided for preventing deposition of material emitted by the deposition source 120 on one or more regions of the substrate 130. For example, the mask 132 may be an edge exclusion shield configured for masking one or more edge regions of the substrate 130, such that no material is deposited on the one or more edge regions during the coating of the substrate 130. As another example, the mask may be a shadow mask for masking a plurality of features, which are deposited on the substrate with the material from the deposition source assembly 110.

The deposition source assembly 110 includes a first active magnetic unit 150. An active magnetic unit, as described herein, may be a magnetic unit adapted for generating an adjustable magnetic field. The adjustable magnetic field may be dynamically adjustable during operation of the apparatus 100. For example, the magnetic field may be adjustable during the emission of material by the deposition source 120 for deposition of the material on the substrate 130 and/or may be adjustable in between deposition cycles of a layer formation process performed by the apparatus 100. Alternatively or additionally, the magnetic field may be adjustable based on a position of the deposition source assembly 110 with respect to the guiding structure. The adjustable magnetic field may be a static or a dynamic magnetic field. According to embodiments, which can be combined with other embodiments described herein, an active magnetic unit is configured for generating a magnetic field for providing a magnetic levitation force extending along a vertical direction. According to other embodiments, which can be combined with further embodiments described herein, an active magnetic unit may be configured for providing a magnetic force extending along a transversal direction, e.g. an opposing magnetic force as described below.

An active magnetic unit, as described herein, may be or include an element selected from the group consisting of: an electromagnetic device; a solenoid; a coil; a superconducting magnet; or any combination thereof.

As shown in FIG. 1, the apparatus 100 may include a guiding structure 170. During operation of the apparatus 100, at least a portion of the guiding structure 170 may face the first active magnetic unit 150. The guiding structure 170 and/or the first active magnetic unit 150 may be arranged at least partially below the deposition source 120. Even though FIG. 1 shows the guiding structure 170 below the first active magnetic unit 150, it is noted that this is just for illustrating and/or schematic purposes. According to some embodiments, which can be combined with other embodiments described herein, the first active magnetic unit 150 is provided below the guiding structure, such that the magnet lens assembly is levitated, wherein the first active magnetic unit hangs below the guiding structure 170. Still, the guiding structure 170 and/or the first active magnetic unit 150 may be arranged at least partially below the deposition source 120.

In operation, the deposition source assembly 110 is movable with respect to the guiding structure along the x-direction. Further, position adjustment may be provided along the y-direction, along the z-direction and/or along an arbitrary spatial direction. The guiding structure is configured for contactless guiding of the movement of the deposition source assembly. During operation, the deposition source assembly 110 may be movably arranged in the processing chamber. The guiding structure 170 may be a static guiding structure. The guiding structure 170 may be statically arranged in the processing chamber.

The guiding structure 170 may have magnetic properties. The guiding structure 170 may be made of a magnetic material, e.g. a ferromagnetic. The guiding structure may be made of ferromagnetic steel. The magnetic properties of the guiding structure 170 may be provided by the material of the guiding structure 170. The guiding structure 170 may be or include a passive magnetic unit.

The terminology of a “passive” magnetic unit is used herein to distinguish from the notion of an “active” magnetic unit. A passive magnetic unit may refer to an element with magnetic properties which are not subject to active control or adjustment, at least not during operation of the apparatus 100. For example, the magnetic properties of a passive magnetic unit, e.g. the guiding structure 170, are not subject to active control during the deposition of material on the substrate 130. According to embodiments, which can be combined with other embodiments described herein, a controller of the apparatus 100 is not configured to control a passive magnetic unit of the deposition source assembly. A passive magnetic unit may be adapted for generating a magnetic field, e.g. a static magnetic field. A passive magnetic unit may not be configured for generating an adjustable magnetic field. A passive magnetic unit may be a permanent magnet or have permanent magnetic properties.

As compared to a passive magnetic unit, an active magnetic unit offers more flexibility and precision in light of the adjustability and controllability of the magnetic field generated by the active magnetic unit. According to embodiments described herein, the magnetic field generated by an active magnetic unit may be controlled to provide for an alignment of the deposition source 120. For example, by controlling the adjustable magnetic field, a magnetic levitation force acting on the deposition source assembly 110 may be controlled with high accuracy, thus allowing for a contactless vertical alignment of the deposition source by the active magnetic unit.

Returning to FIG. 1, the first active magnetic unit 150 is configured for generating an adjustable magnetic field for providing the first magnetic levitation force F1. The magnetic field generated by the first active magnetic unit 150 interacts with the magnetic properties of the guiding structure 170 to provide for a first magnetic levitation force F1, as indicated in FIG. 1. For example, the first magnetic levitation force F1 may result from a magnetic repulsion between the first active magnetic unit 150 and the guiding structure 170. A magnetic levitation force, as described herein, is an upward force extending along a vertical direction. A magnetic levitation force arises from magnetic interaction between the guiding structure 170 and one or more magnetic units, e.g. the first active magnetic unit 150 shown in FIG. 1, or other magnetic units as described herein. A magnetic levitation force acts on the deposition source assembly 110. A magnetic levitation force counteracts, in particular fully counteracts or partially counteracts, the weight G of the deposition source assembly 110. The “weight” of the deposition source assembly 110 refers to the gravitational force acting on the deposition source assembly 110.

In FIG. 1, the weight G of the deposition source assembly 110 is represented by a downward-pointing vector. In the illustrated embodiment, the first magnetic levitation force F1 fully counteracts the weight G of the deposition source assembly 110.

The terminology that a magnetic levitation force “fully” counteracts the weight G of the deposition source assembly 110 entails that the magnetic levitation force suffices to levitate the deposition source assembly 110, i.e. no any additional upward (magnetic or non-magnetic) forces acting on the deposition source assembly 110 are required for providing the contactless levitation. For example, as illustrated in FIG. 1, the forces F1 and G may be equal in size and extend in opposite senses along the y-direction, so that the first magnetic levitation force F1 fully counteracts the weight G of the deposition source assembly 110. As illustrated in FIG. 1, under the action of the first magnetic levitation force F1, the magnetically levitated deposition source assembly 110 is in a floating state without contacting the guiding structure 170.

According to embodiments, which can be combined with other embodiments described herein, the magnitude of the first magnetic levitation force F1 along the y-direction is equal to the magnitude of the weight G.

The apparatus 100 may include a controller (not shown in FIG. 1). The controller may be configured for controlling the first active magnetic unit 150. According to embodiments, which can be combined with other embodiments described herein, the controller may be configured for controlling an adjustable magnetic field generated by the first active magnetic unit 150 to align the deposition source 120 in a vertical direction. For example, by controlling the first active magnetic unit 150, the deposition source assembly 110 may be positioned into a target vertical position. The deposition source assembly 110 may be maintained in the target vertical position, e.g. during a layer formation process performed by the apparatus 100, under the control of the controller. Accordingly, a contactless alignment of the deposition source 120 is provided.

As shown in FIG. 1, the deposition source assembly 110 may include a source support 160. The source support 160 supports the deposition source 120. The source support 160 may be a source cart. The deposition source 120 may be mounted to the source support 160. In operation, the deposition source 120 may be above the source support 160. The first active magnetic unit may be mounted to the source support 160.

In some of the figures, e.g. in FIG. 1, the guiding structure 170 is schematically represented as a rectangular structure which is arranged fully below the deposition source assembly 110. This schematic representation, which is provided for the sake of simplicity and clarity of exposition, shall not be considered as limiting. For any embodiment described herein, other shapes and spatial arrangements of the guiding structure 170 with respect to the deposition source assembly 110 may be provided. For example, the guiding structure 170 may include two parts each having an E-shaped profile, as described below.

FIGS. 2, 3 and 4 show operational states of the apparatus 100 according to embodiments, which can be combined with other embodiments described herein. FIGS. 2, 3 and 4 show a front view of the apparatus 100. As shown, the guiding structure 170 may extend along a source transportation direction. The source transportation direction is a transversal direction as described herein. In the figures, the source transport direction is the x-direction. The guiding structure 170 may have a linear shape extending along the source transport direction. The length of the guiding structure 170 along the source transportation direction may be from 1 m to 6 m.

In the embodiment illustrated in FIGS. 2, 3 and 4, the substrate (not shown) may be arranged substantially parallel to the drawing plane. The substrate may be provided in a substrate receiving area 210 during the layer deposition process. The substrate receiving area 210 defines the area in which the substrate, e.g. a large area substrate, is provided during the layer deposition process. The substrate receiving area 210 has dimensions, e.g. a length and a width, which are the same or slightly (e.g. 5-20%) larger as the corresponding dimensions of the substrate.

During operation of the apparatus 100, the deposition source assembly 110 may be translatable along the guiding structure 170 in the source transportation direction, e.g. the x-direction. FIGS. 2, 3 and 4 show the deposition source assembly 110 at different positions along the x-direction relative to the guiding structure 170. The horizontal arrows indicate a translation of the deposition source assembly 110 from left to right along the guiding structure 170.

The guiding structure 170 may have magnetic properties substantially along the length of the guiding structure 170 in the source transportation direction. The magnetic field generated by the first active magnetic unit 150 interacts with the magnetic properties of the guiding structure to provide for a first magnetic levitation force F1 substantially along the length of the guiding structure in the source transportation direction. Accordingly, a contactless levitation, transportation and alignment of the deposition source 120 may be provided substantially along the length of the guiding structure 170 in the source transportation direction, as illustrated in FIGS. 2, 3 and 4.

According to embodiments, which can be combined with other embodiments described herein, the apparatus 100 may include a drive system configured for driving the deposition source assembly 110 along the guiding structure 170. The drive system may be a magnetic drive system configured for transporting the deposition source assembly 110 without contact along the guiding structure 170 in the source transportation direction. The drive system may be a linear motor. The drive system may be configured for starting and/or stopping movement of the deposition source assembly along the guiding structure. According to some embodiments, which can be combined with other embodiments described herein, the contactless drive system can be a combination of a passive magnetic unit, particularly a passive magnetic unit provided at the guiding structure, and an active magnetic unit, particularly an active magnetic unit provided in or at the deposition source assembly.

According to embodiments, the speed of the deposition source assembly along the source transportation direction may be controlled for controlling the deposition rate. The speed of the deposition source assembly can be adjusted in real-time under the control of the controller. The adjustment can be provided for compensating a deposition rate change. A speed profile may be defined. The speed profile may determine the speed of the deposition source assembly at different positions. The speed profile may be provided to or stored in the controller. The controller may control the drive system such that the speed of the deposition source assembly is in accordance with the speed profile. Accordingly, a real-time control and adjustment of the deposition rate can be provided, so that the layer uniformity can be further improved.

During the contactless movement of the deposition source assembly 110 along the guiding structure 170, the deposition source 120 may emit, e.g. continuously emit, material towards the substrate in the substrate receiving area 210 for coating the substrate. The deposition source assembly 110 may sweep along the substrate receiving area 210 such that, during one coating sweep, the substrate can be coated over the entire extent of the substrate along the source transportation direction. In a coating sweep, the deposition source assembly 110 may start from an initial position and move to a final position without changing direction. According to embodiments, which can be combined with other embodiments described herein, the length of the guiding structure 170 along the source transportation direction may be 90% or more, 100% or more, or even 110% or more of the extent of the substrate receiving area 210 along the source transportation direction. Accordingly, a uniform deposition at the edges of the substrate can be provided.

A translational movement of the deposition source assembly 110 along the source transportation direction, as considered according to embodiments described herein, allows for a high coating precision, in particular a high masking precision during the coating process, since the substrate and the mask can remain stationary during coating.

According to embodiments, which can be combined with other embodiments described herein, the deposition source may be aligned without contact, e.g. vertically, angularly or transversally aligned as described herein, while the deposition source moves along the substrate for depositing material on the substrate. The deposition source may be aligned while the deposition source is transported along the guiding structure. The alignment may be a continuous or an intermittent alignment during the movement of the deposition source. The alignment during the movement of the deposition source may be performed under the control of the controller. The controller may receive information about a current position of the deposition source along the guiding structure. The alignment of the deposition source may be performed under the control of the controller based on information regarding the current position of the deposition source. Accordingly, potential deformations of the guiding structure can be compensated. Accordingly, the deposition source can be maintained at a target distance or a target orientation with respect to the substrate at all times throughout the movement of the deposition source along the substrate, thus further improving the uniformity of the layers deposited on the substrate.

Alternatively or additionally, aligning the deposition source may be performed when the deposition source is static. For example, alignment may be performed for a temporarily static deposition source in between deposition cycles.

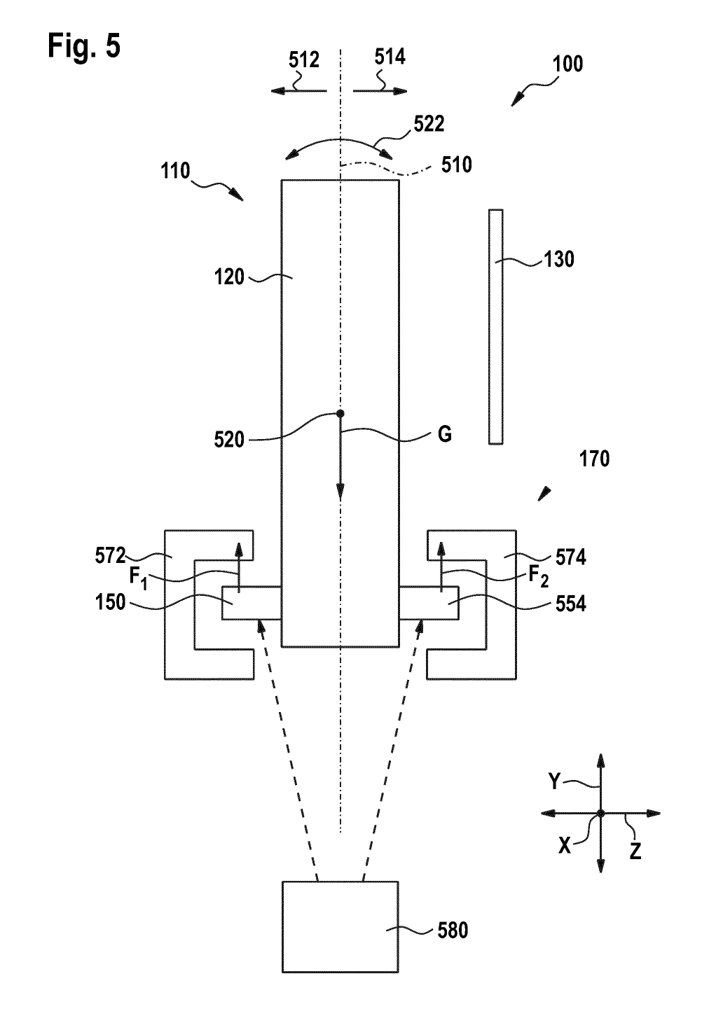

According to an embodiment, and as illustrated in FIG. 5, an apparatus 100 for contactless levitation of a deposition source 120 is provided. The apparatus 100 comprises a deposition source assembly 110 with a first plane 510 including a first rotation axis 520 of the deposition source assembly 110. The deposition source assembly 110 comprises the deposition source 120. The deposition source assembly 110 comprises a first active magnetic unit 150 arranged at a first side 512 of the first plane 510. The deposition source assembly 110 comprises a second active magnetic unit 554 arranged at a second side 514 of the first plane 510. The first active magnetic unit 150 and the second active magnetic unit 554 are configured for magnetically levitating the deposition source assembly 110. The first active magnetic unit 150 and the second active magnetic unit 554 are configured for rotating the deposition source 120 around the first rotation axis 520 for alignment of the deposition source 120.

FIG. 5 shows an operational state of an apparatus 100 according to an embodiment, which can be combined with other embodiments described herein. The deposition source assembly 110 includes a first active magnetic unit 150 and a second active magnetic unit 554. The first active magnetic unit 150 and the second active magnetic unit 554 are each adapted for generating a magnetic field, in particular an adjustable magnetic field, for providing respective magnetic levitation forces acting on the deposition source assembly 110.

A first plane 510 extends through the deposition source assembly 110 shown in FIG. 5. The first plane 510 may extend through a body portion of the deposition source assembly 110. The first plane 510 includes a first rotation axis 520 of the deposition source assembly 110. The first rotation axis 520 may extend through a center of mass of the deposition source assembly 110. In operation, the first plane 510 may extend in a vertical direction. The first plane 510 may be substantially parallel or substantially perpendicular to a substrate receiving area or substrate. In operation, the first rotation axis 520 may extend along a transversal direction.

The first active magnetic unit 150 may be arranged at a first side 512 of the first plane 510. In FIG. 5, the first side 512 of the first plane 510 refers to the left-hand side of the first plane 510. The second active magnetic unit 554 may be arranged at a second side 514 of the first plane 510. In FIG. 5, the second side 514 of the first plane 510 refers to the right-hand side of the first plane 510. The first side 512 is different from the second side 514.

The magnetic field generated by the first active magnetic unit 150 interacts with the magnetic properties of the guiding structure 170 to provide for a first magnetic levitation force F1 acting on the deposition source assembly 110. The first magnetic levitation force F1 acts on a portion of the deposition source assembly 110 on the first side 512 of the first plane 510. In FIG. 5, the first magnetic levitation force F1 is represented by a vector provided on the left-hand side of the first plane 510. According to embodiments, which can be combined with other embodiments described herein, the first magnetic levitation force F1 may at least partially counteract the weight G of the deposition source assembly 110.

The notion that a magnetic levitation force “partially” counteracts the weight G, as described herein, entails that the magnetic levitation force provides a levitation action, i.e. an upward force, on the deposition source assembly 110, but that the magnetic levitation force alone may not suffice to levitate the deposition source assembly 110. The magnitude of a magnetic levitation force which partially counteracts the weight is smaller than the magnitude of the weight G.

The magnetic field generated by the second active magnetic unit 554 shown in FIG. 5 interacts with the magnetic properties of the guiding structure 170 to provide for a second magnetic levitation force F2 acting on the deposition source assembly 110. The second magnetic levitation force F2 acts on a portion of the deposition source assembly 110 on the second side 514 of the first plane 510. In FIG. 5, the second magnetic levitation force F2 is represented by a vector provided on the right-hand side of the first plane 510. The second magnetic levitation force F2 may at least partially counteract the weight G of the deposition source assembly 110.

A superposition of the first magnetic levitation force F1 and the second magnetic levitation force F2 provides for a superposed magnetic levitation force acting on the deposition source assembly 110. The superposed magnetic levitation force may fully counteract the weight G of the deposition source assembly 110. The superposed magnetic levitation force may suffice to provide for a contactless levitation of the deposition source assembly 110, as illustrated in FIG. 5. Yet, further contactless forces may be provided such that the first magnetic levitation force F1 and the second magnetic levitation force F2 provides for a superposed magnetic levitation force may partially counteract the weight G and the first magnetic levitation force F1, the second magnetic levitation force F2, and the further contactless forces provides for a superposed magnetic levitation force to fully counteract the weight G.

According to embodiments, which can be combined with other embodiments described herein, the first active magnetic unit may be configured for generating a first adjustable magnetic field for providing a first magnetic levitation force F1. The second active magnetic unit may be configured for generating a second adjustable magnetic field for providing a second magnetic levitation force F2. The apparatus may include a controller configured for controlling the first adjustable magnetic field and the second adjustable magnetic field for aligning the deposition source.

As shown in FIG. 5, the apparatus 100 may include a controller 580. The controller 580 may be configured for controlling, in particular for individually controlling, the first active magnetic unit 150 and/or the second active magnetic unit 554.

The controller may be configured for controlling the first active magnetic unit and the second active magnetic unit for translationally aligning the deposition source in a vertical direction. By controlling the first active magnetic unit 150 and the second active magnetic unit 554, the deposition source assembly 110 may be positioned into a target vertical position. The deposition source assembly 110 may be maintained in the target vertical position under the control of the controller 580.

An individual control of the first active magnetic unit 150 and/or of the second active magnetic unit 554 may offer an additional benefit with regard to the alignment of the deposition source 120. An individual control allows for a rotation of the deposition source assembly 110 around the first rotation axis 520 for angularly aligning the deposition source 120. For example, with reference to FIG. 5, individually controlling the first active magnetic unit 150 and/or the second active magnetic unit 554 in a manner such that the first magnetic levitation force F1 is greater than the second magnetic levitation force F2 results in a torque which may provide for a clockwise rotation of the deposition source assembly 110 around the first rotation axis 520. Similarly, a second magnetic levitation force F2, which is greater than the first magnetic levitation force F1 may result in a counter-clockwise rotation of the deposition source assembly 110 around the first rotation axis 520.

The rotational degree of freedom provided by the individual controllability of the first active magnetic unit 150 and of the second active magnetic unit 554 (indicated in FIG. 5 by reference numeral 522) allows controlling an angular orientation of the deposition source assembly 110 with respect to the first rotation axis 520. Under the control of the controller 580, a target angular orientation may be provided and/or maintained. The target angular orientation of the deposition source assembly 110 may be a vertical orientation, for example an orientation according to which the first plane 510 is parallel to the y-direction, as illustrated in FIG. 5. Alternatively, a target orientation may be a tilted or slightly tilted orientation according to which the first plane 510 is inclined at a target angle with respect to the y-direction.

According to embodiments, which can be combined with other embodiments described herein, the controller is configured for controlling the first active magnetic unit and the second active magnetic unit for angularly aligning the deposition source with respect to the first rotation axis.

With regard to the spatial arrangement of the first active magnetic unit 150 and the second active magnetic unit 554 in the deposition source assembly 110, embodiments described herein provide several options.

For example, the arrangement of the first active magnetic unit 150 and the second active magnetic unit 554 may be such that, in an operational state of the apparatus, the first plane 510 is substantially parallel to the substrate 130 and/or substrate receiving area. In the schematic illustration of FIG. 5, the first plane 510 and the substrate 130 are parallel to each other and both extend perpendicularly to the drawing plane.

During operation of the apparatus 100, the first rotation axis 520 may extend along a transversal direction. As illustrated in FIG. 5, the first rotation axis 520 may be parallel or substantially parallel to the x-direction and/or to the source transportation direction. Accordingly, embodiments described herein allow controlling the angular orientation of the deposition source assembly 110 with respect to a first rotation axis 520 which is parallel or substantially parallel to the x-direction or source transportation direction.

As shown in FIG. 5, the guiding structure 170 may include a first portion 572 and a second portion 574.

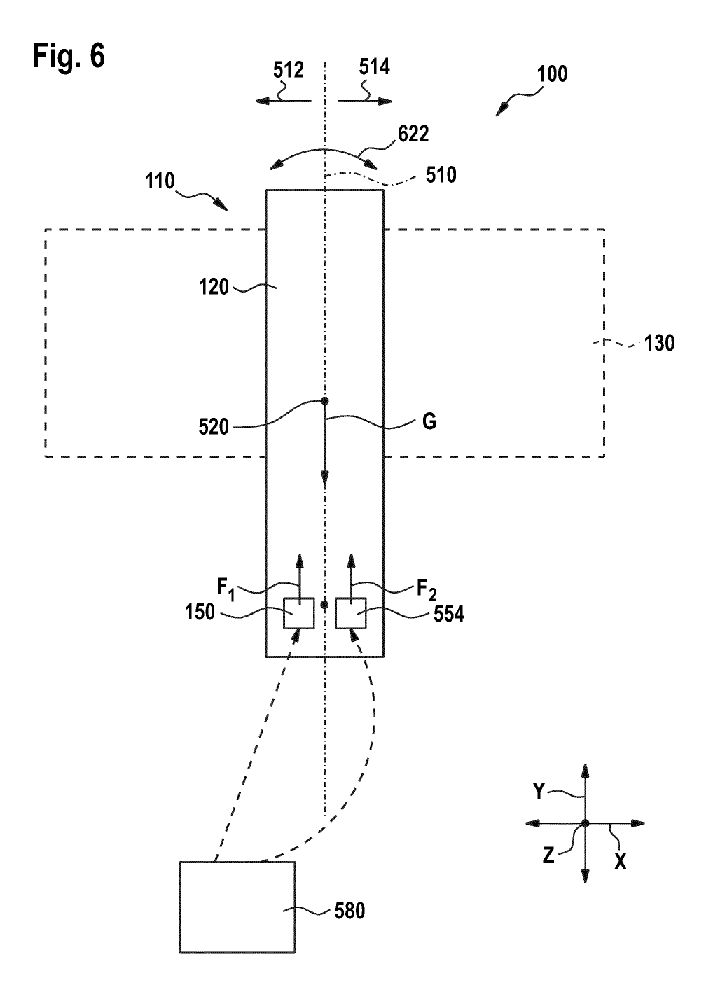

As a further example, and as shown in FIG. 6, the arrangement of the first active magnetic unit 150 and the second active magnetic unit 554 in the deposition source assembly 110 may be such that, in operation, the first plane 510 is substantially perpendicular to the substrate 130 or substrate receiving area. In the schematic illustration of FIG. 6, the first plane 510 is perpendicular to the drawing plane and the substrate 130 is arranged parallel to the drawing plane.

As illustrated in FIG. 6, the first rotation axis 520 may be perpendicular or substantially perpendicular to the x-direction or source transportation direction. Accordingly, by individually controlling the first active magnetic unit 150 and/or the second active magnetic unit 554, embodiments described herein allow controlling the angular orientation of the deposition source assembly 110 with respect to a first rotation axis 520 which is perpendicular or substantially perpendicular to the x-direction or source transportation direction. The rotational degree of freedom with respect to the first rotation axis 520 is indicated in FIG. 6 with reference numeral 622.

For the sake of clarity, the guiding structure is not shown in FIG. 6. However, it shall be understood that a guiding structure according to embodiments described herein may be included in the apparatus 100 shown in FIGS. 5 and 6.

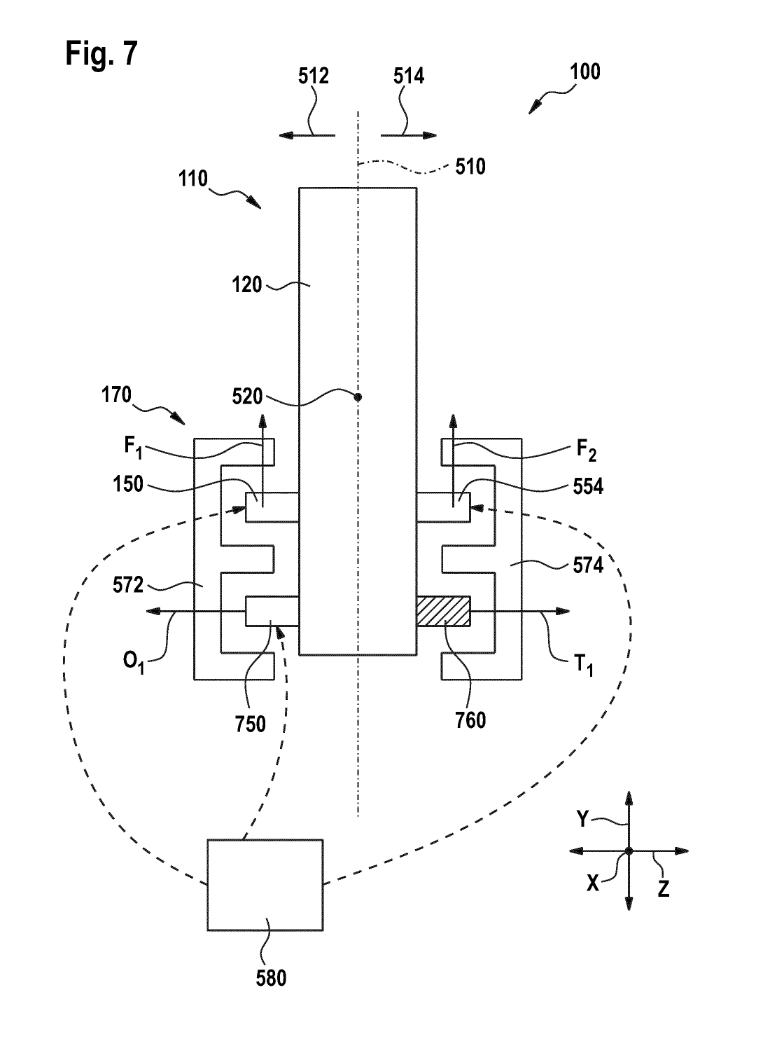

According to an embodiment, and as illustrated in FIG. 7, an apparatus 100 for contactless levitation and transversal positioning is provided. The apparatus 100 includes a guiding structure 170. The apparatus 100 includes a first active magnetic unit 150. The first active magnetic unit 150 and the guiding structure 170 are configured for providing a first magnetic levitation force. The apparatus 100 includes a first passive magnetic unit 760. The first passive magnetic unit 760 and the guiding structure 170 are configured for providing a first transversal force F1. The apparatus 100 includes a further active magnet unit 750. The further active magnetic unit 750 and the guiding structure 170 are configured for providing a first opposing transversal force. The first opposing transversal force is an adjustable force counteracting the first transversal force. The apparatus 100 includes a controller 580 configured for controlling the further active magnet unit 750 to provide for a transversal alignment.

FIG. 7 shows an apparatus 100 according to an embodiment, which can be combined with other embodiments described herein. Similar to the embodiment described with respect to FIGS. 5 and 6, the deposition source assembly 110 shown in FIG. 7 includes a first active magnetic unit 150 for providing a first magnetic levitation force F1 and includes a second active magnetic unit 554 for providing a second magnetic levitation force F2 as described herein. The first magnetic levitation force F1 and the second magnetic levitation force F2 may each partially counteract the weight G of the deposition source assembly. Alternatively, the embodiment described with respect to FIG. 7 can include a first active magnetic unit 150 without the second active magnetic unit 554, similar to FIG. 1, wherein the first magnetic levitation force F1 fully counteracts the weight G.

As shown in FIG. 7, the deposition source assembly 110 may include a first passive magnetic unit 760, e.g. a permanent magnet. The first passive magnetic unit 760 may be arranged at the second side 514 of the first plane 510. In operation, the first passive magnetic unit 760 may face the second portion 574 of the guiding structure 170 and/or may be provided between the first plane 510 and the second portion 574.

The first passive magnetic unit 760 may be configured for generating a magnetic field. The magnetic field generated by the first passive magnetic unit 760 may interact with the magnetic properties of the guiding structure 170 to provide for a first transversal force T1 acting on the deposition source assembly 110. The first transversal force T1 is a magnetic force. The first transversal force T1 extends along a transversal direction, as described herein. The first transversal force T1 may extend along a direction substantially perpendicular to the source transportation direction. For example, the first transversal force T1 may be substantially parallel to the z-direction, as shown in FIG. 7.

According to embodiments, which can be combined with other embodiments described herein, the deposition source assembly 110 may include a further active magnetic unit 750. The further active magnetic unit 750 may be arranged at the first side 512 of the first plane 510. In operation, the further active magnetic unit 750 may face the first portion 572 of the guiding structure 170 and/or may be provided at least partially between the first plane 510 and the first portion 572.

The further active magnetic unit 750 may be of a same type as the first active magnetic unit 150, as the second active magnetic unit 554, or as any other active magnetic unit described herein. For example, the further active magnetic unit 750, the first active magnetic unit 150 and/or the second active magnetic unit 554 may be electromagnets of a same type. As compared to the first active magnetic unit 150 and the second active magnetic unit 554, the further active magnetic unit 750 may have a different spatial orientation. In particular, with respect to e.g. the first active magnetic unit 150, the further active magnetic unit 750 may be rotated, e.g. by about 90 degrees, around a transversal axis perpendicular to the drawing plane of FIG. 7. The further active magnetic unit 750 may be configured for generating a magnetic field, in particular an adjustable magnetic field. The magnetic field generated by the further active magnetic unit 750 interacts with the magnetic properties of the guiding structure 170 to provide for a first opposing transversal force O1 acting on the deposition source assembly 110. The first opposing transversal force O1 is a magnetic force.

The first opposing transversal force O1 extends along a transversal direction. The transversal direction may be the same as, or substantially parallel to, the transversal direction along which the first transversal force T1 extends. For example, the forces T1 and O1 shown in FIG. 7 both extend along the z-direction.

The first opposing transversal force O1 and the first transversal force T1 are opposing or counteracting forces. This is illustrated in FIG. 7 by the aspect according to which the forces T1 and O1 are represented by vectors of equal lengths pointing in opposite senses along the z-direction. The first opposing transversal force O1 and the first transversal force T1 may have equal magnitudes. The first opposing transversal force O1 and the first transversal force T1 may extend in opposite senses along a transversal direction. The first transversal force T1 and the first opposing transversal force O1 may be substantially perpendicular to a substrate receiving area or substrate or source transportation direction.

For example, as illustrated in FIG. 7, the first transversal force T1 may result from a magnetic attraction between the first passive magnetic unit 760 and the guiding structure 170. The magnetic attraction urges the first passive magnetic unit 760 towards the guiding structure 170, in particular towards the second portion 574 of the guiding structure 170. The first opposing transversal force O1 may result from a magnetic attraction between the further active magnetic unit 750 and the guiding structure 170. The magnetic attraction urges the further active magnetic unit 750 towards the guiding structure 170, in particular towards the first portion 572 of the guiding structure 170. Accordingly, the forces T1 and O1 illustrated in FIG. 6 are counteracting forces.

Alternatively, the first transversal force T1 may result from a magnetic repulsion between the first passive magnetic unit 760 and the guiding structure 170. The first opposing transversal force O1 may result from a magnetic repulsion between the further active magnetic unit 750 and the guiding structure 170. Also in this case, the forces T1 and O1 are counteracting forces.

The first opposing transversal force O1 may fully counteract the first transversal force T1. The first opposing force O1 may counteract the first transversal force T1 such that the net force acting on the deposition source assembly 110 along a transversal direction, e.g. the z-direction, is zero. Accordingly, the deposition source assembly 110 may be held without contact at a target position along a transversal direction.

As illustrated in FIG. 7, the controller 580 may be configured for controlling the further active magnetic unit 750. The control of the further active magnetic unit 750 may include a control of an adjustable magnetic field generated by the further active magnetic unit 750 for controlling the first opposing transversal force O1. Controlling the further active magnetic unit 750 may allow for a contactless alignment of the deposition source 120 along a transversal direction, e.g. the z-direction. In particular, by suitably controlling the further active magnetic unit 750, the deposition source assembly 110 may be positioned into a target position along a transversal direction. The deposition source assembly 110 may be maintained in the target position under the control of the controller 580.

The first transversal force T1, being provided by a passive magnetic unit, is a static force which is not subject to adjustment or control during operation of the apparatus 100. In this sense, the first transversal force T1 is similar to a gravitational force, the latter force also being a static force not subject to adjustment by an operator. As found by the inventors, the first transversal force T1 may be considered as a force which simulates a hypothetical “gravitational-type” force acting along a transversal direction. For example, the first transversal force T1 can be considered to simulate a hypothetical weight, along a transversal direction, of an object. In turn, within this paradigm, the first opposing transversal force O1 may be considered to simulate a hypothetical “levitation-type” force counteracting the hypothetical weight of the object along the transversal direction. Accordingly, the contactless transversal alignment of the deposition source 120, as provided by a control of the further active magnetic unit 750 for counteracting the first transversal force T1, can be understood from the same principles as the contactless vertical alignment of the deposition source 120, as provided by a control of the first active magnetic unit 150 for counteracting the actual, i.e. vertical, weight G of the deposition source assembly 110. Accordingly, the control of the further active magnetic unit 750 for transversally aligning the deposition source 120 may be performed using the same technology and based on the same control algorithms as are used for the control of the first active magnetic unit 150 for providing vertical alignment. This provides for a simplified approach for aligning the deposition source.

According to embodiments, which can be combined with other embodiments described herein, the first portion 572 and the second portion 574 of the guiding structure 170 may be separate parts of the guiding structure 170. In operation, the first portion 572 of the guiding structure 170 may be arranged at the first side 512 of the first plane 510. The second portion 574 of the guiding structure 170 may be arranged at the second side of the first plane 510.

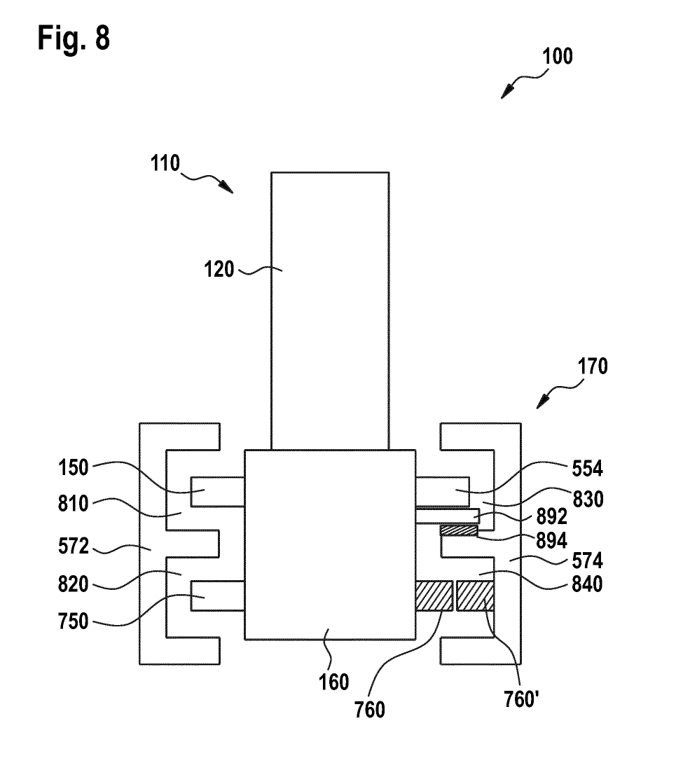

According to embodiments, which can be combined with other embodiments described herein, one or more, or all, of the magnetic units included in the deposition source assembly 110 may be mounted to the source support 160. For example, as shown in FIG. 8, the first active magnetic unit 150, the second active magnetic unit 554, the first passive magnetic unit 760 and/or the further active magnetic unit 750, as described herein, may be mounted to the source support 160.

The first portion 572 and the second portion 574 of the guiding structure 170 may each be passive magnetic units and/or may include one or more passive magnet assemblies. For example, the first portion 572 and the second portion 574 may each be made of a ferromagnetic material, e.g. ferromagnetic steel. The first portion 572 may include a recess 810 and a recess 820. In operation, a magnetic unit of the deposition source assembly 110, e.g. the first active magnetic unit 150 as shown in FIG. 8, may be at least partially arranged in the recess 810. In operation, another magnetic unit of the deposition source assembly, e.g. the further active magnetic unit 750, may be at least partially arranged in the recess 820. The first portion 572 of the guiding structure 170 may have an E-shaped profile in a cross-section perpendicular to the source transport direction, e.g. the x-direction. An E-shaped profile substantially along the length of the first portion 572 may define the recess 810 and the recess 820. Similarly, the second portion 574 may include a recess 830 and a recess 840. In operation, a magnetic unit of the deposition source assembly 110, e.g. the second active magnetic unit 554 as shown in FIG. 8, may be at least partially arranged in the recess 830. In operation, another magnetic unit of the deposition source assembly 110, e.g. the first passive magnetic unit 760, may be at least partially provided in the recess 840. The first passive magnetic unit 760 may interact with a further passive magnetic unit 760′ provided at the guiding structure 170. The second portion 574 may have an E-shaped profile in a cross-section perpendicular to the source transportation direction. An E-shaped profile substantially along the length of the second portion 574 may define the recess 830 and the recess 840.

According to some embodiments of the present disclosure, a passive magnetic drive unit 894 may be provided at the guiding structure. For example, the passive magnetic drive unit 894 can be a plurality of permanent magnets, particularly a plurality of permanent magnets forming a passive magnet assembly with varying pole orientation. The plurality of magnets can have alternating pole orientation to form the passive magnet assembly. An active magnetic drive unit 892 can be provided at or in the source assembly, e.g. the source support 160. The passive magnetic drive unit 894 and the active magnetic drive unit 892 can provide the drive, e.g. a contactless drive, for movement along the guiding structure, while the source assembly is levitated. According to embodiments, which can be combined with other embodiments described herein, the guiding structure includes a first portion defining an E-shaped profile and includes a second portion defining an E-shaped profile. The first portion may include two recesses each adapted for receiving one or more magnetic units of the deposition source assembly. The second portion may include two recesses each adapted for receiving one or more magnetic units of the deposition source assembly.

By arranging the magnetic units of the deposition source assembly 110 at least partially in the respective recesses of the guiding structure 170, an improved magnetic interaction between the guiding structure and the magnetic units in the respective recess is obtained for providing the forces F1, F2, T1 and/or O1 as described herein.

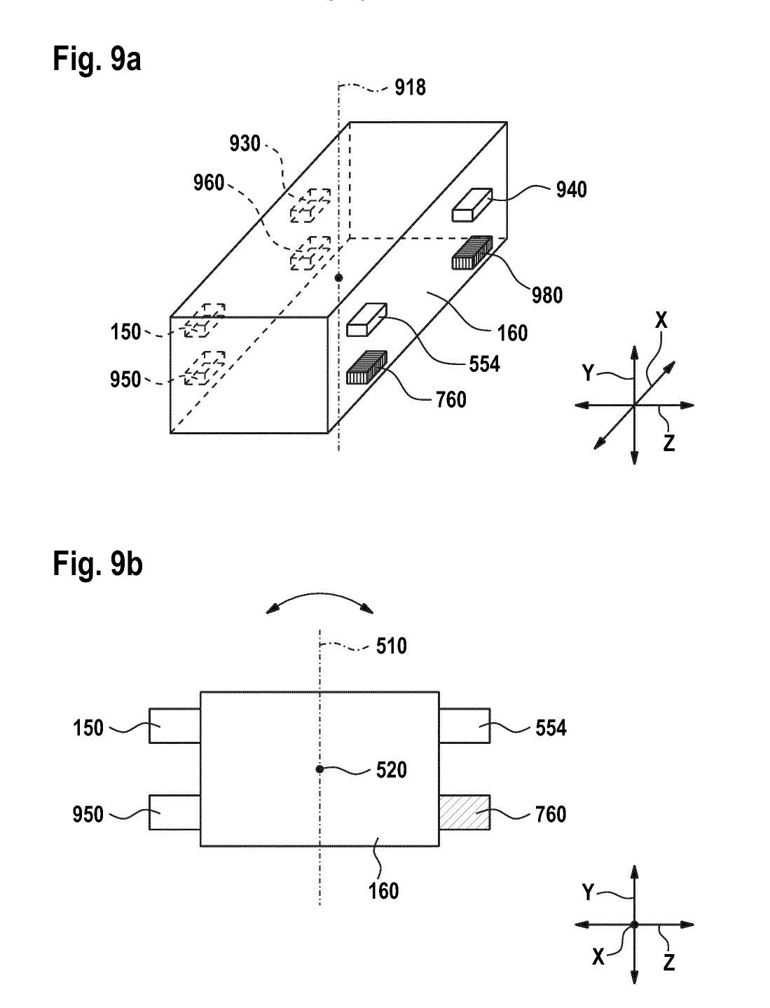

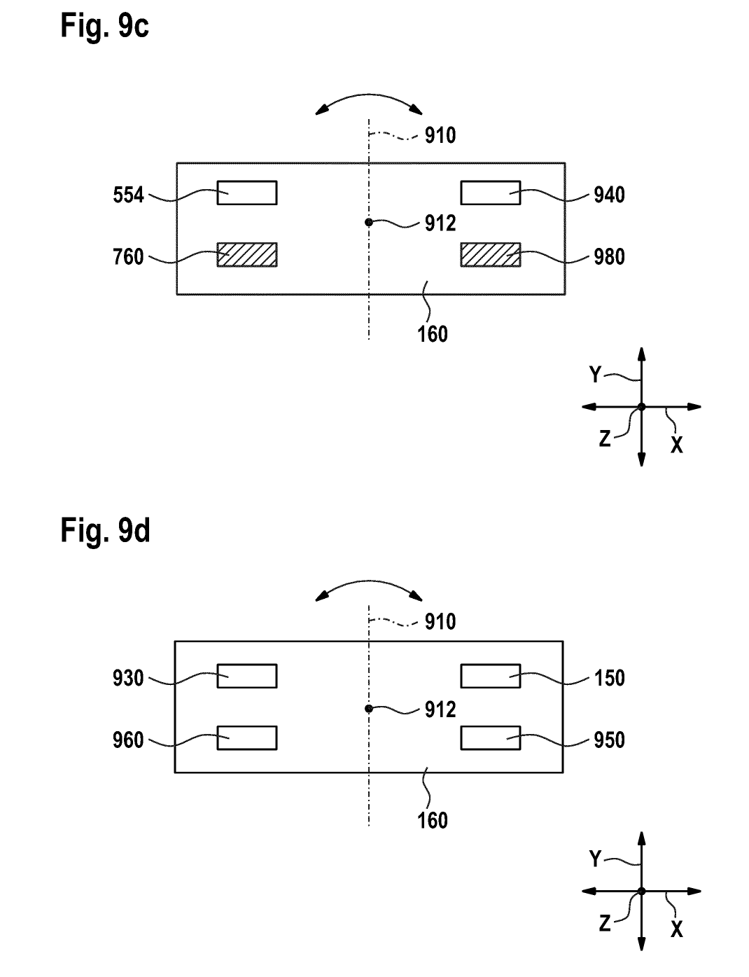

According to embodiments, which can be combined with other embodiments described herein, the deposition source assembly 110 comprises a third active magnetic unit configured for magnetically levitating the evaporation source assembly. According to embodiments, which can be combined with other embodiments described herein, the deposition source assembly 110 comprises a fourth active magnetic unit configured for magnetically levitating the evaporation source assembly. FIG. 9a shows a third active magnetic unit 930 and a fourth active magnetic unit 940.

FIGS. 9a-d show a source support 160, e.g. a source cart, according to embodiments which can be combined with other embodiments described herein. As shown, the following units may be mounted to the source support 160: the deposition source 120; a first active magnetic unit 150; a second active magnetic unit 554; a third active magnetic unit 930; a fourth active magnetic unit 940; a fifth active magnetic unit 950; a sixth active magnetic unit 960; a first passive magnetic unit 760; a second passive magnetic unit 980; or any combination thereof. The fifth active magnetic unit 950 may be a further active magnetic unit 750 as described herein. Yet further, an active magnetic drive unit 892 can be provided as shown in FIG. 8.

FIGS. 9b, 9c and 9d show a side view, a back view, a front view, respectively, of the source support 160 shown in FIG. 9a.

FIG. 9b shows the first plane 510, as described herein, extending through the source support 160. The first plane 510 includes the first rotation axis 520, as described herein. As shown in FIG. 9b, in operation, the first rotation axis 520 may be substantially parallel to the x-direction.

In operation, the first rotation axis may extend along a transversal direction, e.g. substantially parallel to the x-direction. The first active magnetic unit 150, the third active magnetic unit 930, the fifth active magnetic unit 950 and/or the sixth active magnetic unit 960 may be arranged on a first side of the first plane 510. The second active magnetic unit 554, the fourth active magnetic unit 940, the first passive magnetic unit 760 and the second passive magnetic unit 980 may be arranged on a second side of the first plane 510.

FIG. 9c shows a second plane 910 extending through the source support 160. Not limited to the embodiment shown in FIG. 9c, the second plane 910 may be perpendicular to the first plane. During operation of the apparatus 100, the second plane may extend in a vertical direction. During operation, the first plane 510 may be substantially parallel to a substrate receiving area or substrate. The second plane 910 may be substantially perpendicular to the substrate receiving area.

The second plane 910 includes a second rotation axis 912 of the deposition source assembly. The second rotation axis 912 may be substantially perpendicular to the first rotation axis. In operation, the second rotation axis 912 may extend along a transversal direction, e.g. substantially parallel to the z-direction, as shown in FIG. 9c.

The first active magnetic unit 150, the second active magnetic unit 554, the fifth active magnetic unit 950 and/or the first passive magnetic unit 760 may be arranged on a first side of the second plane 910. The third active magnetic unit 930, the fourth active magnetic unit 940, the sixth active magnetic unit 960 and the second passive magnetic unit 980 may be arranged on a second side of the second plane 910.

In operation, the source support 160 shown in FIGS. 9a-d, with the eight magnetic units mounted thereon, may be arranged with respect to a guiding structure including a first portion and a second portion having E-shaped profiles defining recesses as shown in FIG. 8. The first active magnetic unit 150 and the third active magnetic unit 930 may be at least partially arranged in the recess 810. The fifth active magnetic unit 950 and the sixth active magnetic unit 960 may be at least partially arranged in the recess 820. The second active magnetic unit 554 and the fourth active magnetic unit 940 may be at least partially arranged in the recess 830. The first passive magnetic unit 760 and the second passive magnetic unit 980 may be at least partially arranged in the recess 840.

Each of the first active magnetic unit 150, the second active magnetic unit 554, the third active magnetic unit 930 and the fourth active magnetic unit 940 may be configured for providing a magnetic levitation force acting on the deposition source assembly. Each of these four magnetic levitation forces may partially counteract the weight of the deposition source assembly. The superposition of these four magnetic levitation forces may provide for a superposed magnetic levitation force which fully counteracts the weight of the deposition source assembly, such that a contactless levitation may be provided.

By controlling the first active magnetic unit 150, the second active magnetic unit 554, the third active magnetic unit 930 and the fourth active magnetic unit 940, the deposition source may be translationally aligned along a vertical direction. Under the control of the controller, the deposition source may be positioned in a target position along a vertical direction, e.g. the y-direction.

By controlling, in particular individually controlling, the first active magnetic unit 150, the second active magnetic unit 554, the third active magnetic unit 930 and the fourth active magnetic unit 940, the deposition source assembly may be rotated around the first rotation axis. Similarly, by controlling the units 150, 554, 930 and 940, the deposition source assembly may be rotated around the second rotation axis. The control of the active magnetic units 150, 554, 930 and 940 allows controlling the angular orientation of the deposition source assembly with respect to the first rotation axis and the angular orientation with respect to the second rotation axis for aligning the deposition source. Accordingly, two rotational degrees of freedom for angularly aligning the deposition source can be provided.

The first passive magnetic unit 760 and the second passive magnetic unit 980 are configured for providing a first transversal force T1 and a second transversal force T2, respectively. The fifth active magnetic unit 950 and the sixth active magnetic unit 960 are configured for providing a first opposing transversal force O1 and a second opposing transversal force O2, respectively. In analogy to the discussion provided with respect to FIG. 7, the first opposing force O1 and the second opposing force O2 counteract the first transversal force T1 and the second transversal force T2.

By controlling the fifth active magnetic unit 950 and the sixth active magnetic unit 960, and hence controlling the forces T1 and T2, the deposition source may be translationally aligned along a transversal direction, e.g. the z-direction. Under the control of the controller, the deposition source may be positioned in a target position along a transversal direction.

By individually controlling the fifth active magnetic unit 950 and the sixth active magnetic unit 960, the deposition source assembly may be rotated around a third rotation axis 918, as shown in FIG. 9a. The third rotation axis 918 may be perpendicular to the first rotation axis 520 and/or may be perpendicular to the second rotation axis 912. In operation, the third rotation axis 918 may extend along a vertical direction. The individual control of the fifth active magnetic unit 950 and the sixth active magnetic unit 960 allows controlling the angular orientation of the deposition source assembly with respect to the third rotation axis 918 for angularly aligning the deposition source.

Similar to the discussion provided above, the transversal forces T1 and T2 may be considered to simulate hypothetical “gravitational-type” forces acting along a transversal direction. The opposing forces O1 and O2 may be considered to simulate hypothetical “levitation-type” forces along a transversal direction. Accordingly, the angular alignment of the deposition source with respect to the third rotation axis can be understood from the same principles as the angular alignment of the deposition source with respect to, e.g., the first rotation axis. Accordingly, the control of the fifth active magnetic unit 950 and the sixth active magnetic unit 960 for rotationally aligning the deposition source with respect to the third rotation axis may be performed based on the same control algorithms as are used for the angular alignment with respect to the first rotation axis.

According to embodiments, which can be combined with other embodiments described herein, the deposition source assembly includes a third active magnetic unit and a fourth active magnetic unit configured for magnetically levitating the evaporation source assembly. The third active magnetic unit may be arranged at a first side of a first plane of the deposition source assembly. The fourth active magnetic unit may be arranged at a second side of the first plane. The first active magnetic unit, the second active magnetic unit, the third active magnetic unit and the fourth active magnetic unit may be configured for rotating the deposition source around a first rotation axis of the deposition source assembly and around a second rotation axis of the deposition source assembly for alignment of the deposition source.

The third active magnetic unit may be configured for generating a third adjustable magnetic field for providing a third magnetic levitation force. The fourth active magnetic unit may be configured for generating a fourth adjustable magnetic field for providing a fourth magnetic levitation force. The controller may be configured for controlling the third adjustable magnetic field and the fourth adjustable magnetic field for aligning the deposition source, particularly for translationally aligning and/or for angularly aligning the deposition source. An angular alignment may be performed with respect to the first rotation axis and/or with respect to the second rotation axis.

According to embodiments, which can be combined with other embodiments described herein, the apparatus may include a second passive magnetic unit. The second passive magnetic unit and the guiding structure may be configured for providing a second transversal force T2.

The apparatus may include a second further active magnet unit. The second further active magnetic unit and the guiding structure are configured for providing a second opposing transversal force O2 for counteracting the second transversal force. The first active magnetic unit may be of a same type as the second further active magnetic unit.

The controller may be configured for controlling the further active magnetic unit and the second further active magnet unit to provide for an angular alignment with respect to a vertical rotation axis, e.g. a third rotation axis 918 as shown in FIG. 9a. According to embodiments, the controller is not configured for controlling the second passive magnetic unit for providing transversal alignment.

According to embodiments, which can be combined with other embodiments described herein, the source support may include one or more, e.g. two, active magnetic units arranged between the first active magnetic unit 150 and the third active magnetic unit 930. The one or more active magnetic units may each be configured for generating a magnetic levitation force.

According to embodiments, which can be combined with other embodiments described herein, the source support may include one or more, e.g. two, active magnetic units arranged between the second active magnetic unit 554 and the fourth active magnetic unit 940. The one or more active magnetic units may each be configured for generating a magnetic levitation force.

A deposition source, as described herein, is not restricted to a single type of deposition source. Several types of deposition sources may be provided.

According to embodiments, which can be combined with other embodiments described herein, a deposition source may be an evaporation source. An evaporation source may be configured for deposition of organic materials, e.g. for OLED display manufacturing on large area substrates. An evaporation source may be mounted to a source support as described herein.

An evaporation source may have a linear shape. In operation, the evaporation source may extend in a vertical direction. For example, the length of the evaporation source can correspond to the height of the substrate. In many cases, the length of the evaporation source will exceed the height of the substrate, e.g. by 10% or more or even 20% or more. A uniform deposition at the upper end of the substrate and/or the lower end of the substrate can be provided.

An evaporation source may include an evaporation crucible. The evaporation crucible may be configured to receive organic material and to evaporate the organic material. The organic material may be evaporated using a heating unit included in the evaporation source. The evaporated material may be emitted towards the substrate.

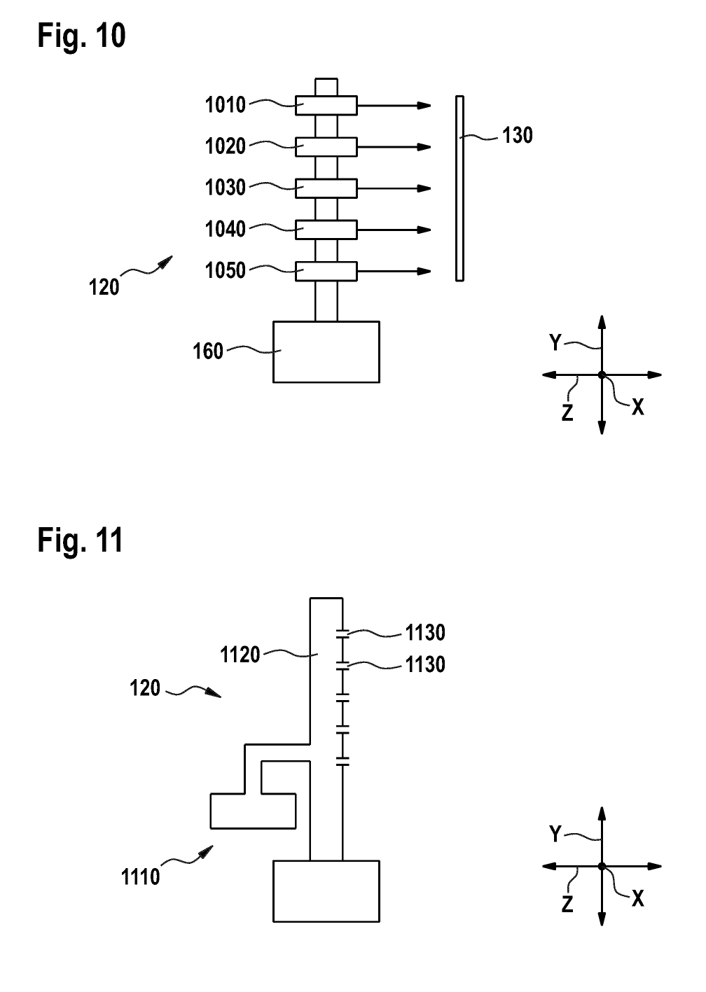

In an example, as illustrated in FIG. 10, an evaporation source 1100 may include a plurality of point sources, e.g. point sources 1010, 1020, 1030, 1040 and 1050 arranged for example along a line. For example, an evaporation source 1100 may include two or more evaporation crucibles arranged along the line. In operation, the line may extend vertically. Each point source is may include a distribution pipe for distributing the evaporated materials towards a desired direction and is configured for evaporating material and for emitting the evaporated material towards the substrate 130, e.g. a vertically oriented substrate. The emission of material from each point source is illustrated in FIG. 10 with arrows emerging from the respective point sources. Each point source may include an evaporation crucible configured for receiving organic material and for evaporating the organic material.

In another example, an evaporation source 1100 may provide for a line source, as illustrated in FIG. 11. An evaporation source 1100 may include an evaporation crucible 1110 and a distribution pipe 1120, e.g. a linear vapor distribution showerhead. A plurality of openings and/or nozzles of the distribution pipe 1120, indicated in FIG. 11 with reference numeral 1130, may be arranged along a line. In operation, the line may extend along a vertical direction. The organic material evaporated in the evaporation crucible 1110 passes from the evaporation crucible 1110 to the distribution pipe 1120 and may be emitted from the distribution pipe 1120 towards the substrate 130 through the openings or nozzles. Accordingly, a line source is provided. According to yet further embodiments, which can be combined with other embodiments described herein, the evaporation crucible can be provided below the distribution pipe.

According to another embodiment, which can be combined with embodiments described herein, a deposition source can be a sputter deposition source. A sputter deposition source may include one or more sputter cathodes, e.g. rotatable cathodes. The cathodes can be planar or cylindrical cathodes having a target material to be deposited on the substrate. A sputter deposition process can be a DC sputters source, and (middle frequency) MF sputters source or an RF frequency (RF: radio frequency) sputter deposition process. As an example, a RF sputter deposition process can be used when the material to be deposited on the substrate is a dielectric material. Frequencies used for RF sputter processes can be about 13.56 MHZ or higher. A sputter deposition process can be conducted as magnetron sputtering. The term “magnetron sputtering” refers to sputtering performed using a magnet assembly, e.g., a unit capable of generating a magnetic field. Such a magnet assembly can include or consist of a permanent magnet. The permanent magnet can be arranged within a rotatable target or coupled to a planar target in a manner such that free electrons are trapped within the generated magnetic field generated below a rotatable target surface. The magnet assembly can also be arranged coupled to a planar cathode.

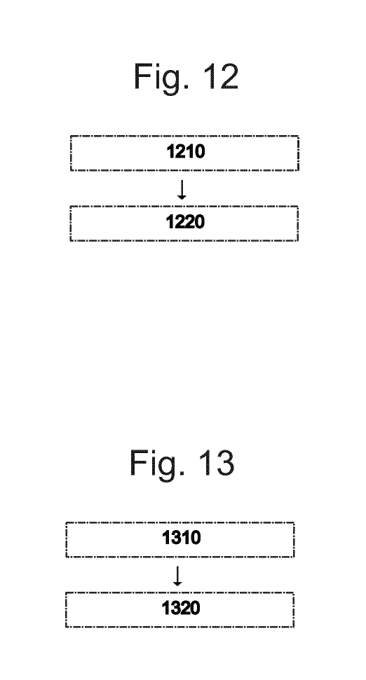

According to an embodiment, which can be combined with other embodiments described herein, a method for contactlessly aligning a deposition source is provided. The method is illustrated in the flow diagram shown in FIG. 12. The method includes generating an adjustable magnetic field to levitate the deposition source, as indicated in FIG. 12 by box 1210. The method includes controlling the adjustable magnetic field to align the deposition source, as indicated in FIG. 12 with box 1220.

The adjustable magnetic field may be generated by any of the active magnetic units described herein which are configured for generating a magnetic levitation force, or any combination of such active magnetic units. The contactless levitation of the deposition source may be provided by an interaction between the adjustable magnetic field and magnetic properties of a guiding structure as described herein. Controlling the adjustable magnetic field may be performed by a controller as described herein. Controlling the adjustable magnetic field to align the deposition source may include any contactless alignment of the deposition source as described herein, e.g. a translational alignment or an angular alignment.

According to an embodiment, which can be combined with other embodiments described herein, a method for contactlessly aligning a deposition source is provided. The method is illustrated in the flow diagram shown in FIG. 13. The method includes providing a first magnetic levitation force F1 and a second magnetic levitation F2 force to levitate the deposition source, as indicated in FIG. 13 with box 1310. The first magnetic levitation force F1 is distanced from the second magnetic levitation force F2. The method includes controlling at least one of the first magnetic levitation force F1 and the second magnetic levitation force F2 to align the deposition source, as indicated in FIG. 13 with box 1320.

Controlling at least one of the first magnetic levitation force F1 and the second magnetic levitation force F2 may be performed by a controller as described herein. Controlling the forces F1 and/or F2 to align the deposition source may include a contactless angular alignment of the deposition source as described herein.

According to embodiments, which can be combined with other embodiments described herein, a method may include providing a third magnetic levitation force and a fourth magnetic levitation force to levitate the deposition source. The third magnetic levitation force may be distanced from the fourth magnetic levitation force. At least one of the first magnetic levitation force, the second magnetic levitation force, the third magnetic levitation force and the fourth magnetic levitation force are configured for rotating the deposition source with respect to a first rotation axis and with respect to a second rotation axis. At least one of the first magnetic levitation force, the second magnetic levitation force, the third magnetic levitation force and the fourth magnetic levitation force may be controlled to align the deposition source.

According to embodiments, which can be combined with other embodiments described herein, a method may include providing a first transversal force acting on the deposition source. The first transversal force is provided using a first passive magnetic unit. A method may include providing a first opposing transversal force acting on the deposition source. The first opposing transversal force is an adjustable magnetic force counteracting the first transversal force. A method may include controlling, e.g. by a controller as described herein, the first opposing transversal force to provide for a transversal alignment of the deposition source.

According to embodiments, which can be combined with other embodiments described herein, the alignment, e.g. a translational, rotational or transversal alignment, of the deposition source is performed when the deposition source is in a first position. For example, the first position may refer to the position of the deposition source 120 shown in FIG. 2.

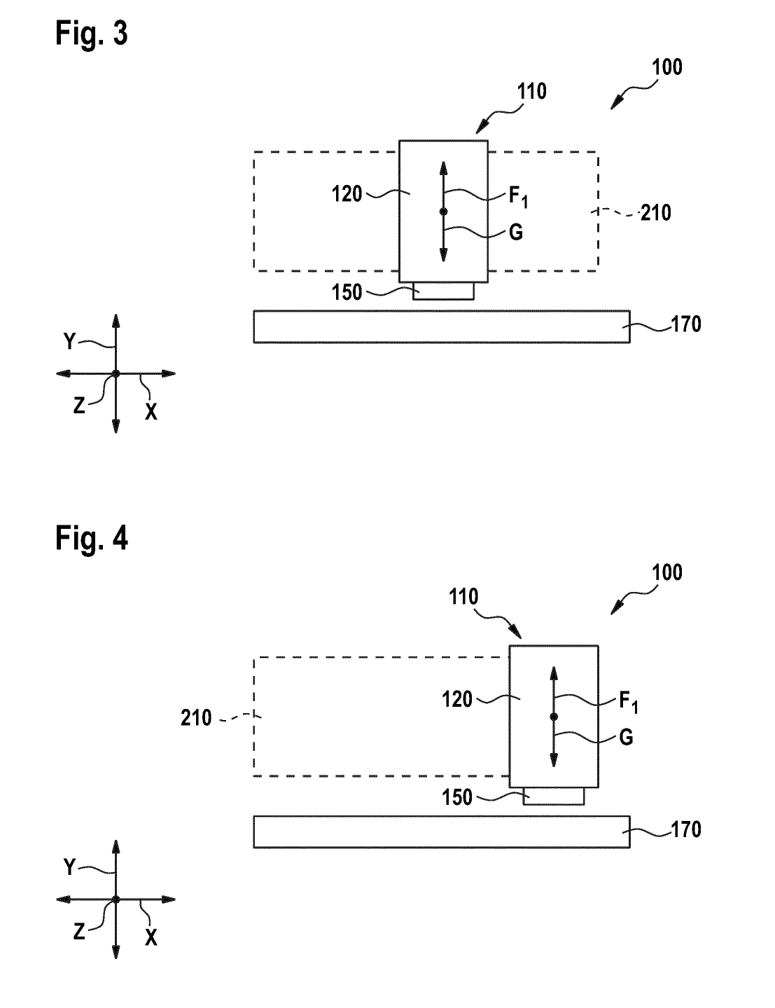

According to embodiments, which can be combined with other embodiments described herein, a method may include transporting the deposition source from the first position to a second position. For example, the second position may refer to the position of the deposition source 120 shown in FIG. 3 or FIG. 4. The method may include contaclessly aligning the deposition source when the deposition source is in the second position.

According to embodiments, which can be combined with other embodiments described herein, a method may include moving the deposition source from the first position to the second position while material is emitted from the deposition source. The emitted material may be deposited on a substrate for forming a layer on the substrate.

The embodiments of the methods described herein can be performed using any of the embodiments of the apparatuses described herein. Conversely, the embodiments of the apparatuses described herein are adapted for performing any of the embodiments of the methods described herein.

While the foregoing is directed to embodiments of the disclosure, other and further embodiments of the disclosure may be devised without departing from the basic scope thereof, and the scope thereof is determined by the claims that follow.

1. An apparatus for contactless transportation of a deposition source, comprising:
a deposition source assembly, comprising:
the deposition source; and
a first active magnetic unit; and
a guiding structure with magnetic properties extending in a source transportation direction, wherein the deposition source assembly is movable along the guiding structure, wherein the first active magnetic unit and the guiding structure are configured for providing a first magnetic levitation force (FI) for levitating the deposition source assembly, wherein the apparatus further comprise a controller configured for controlling the first active magnetic unit to align the deposition source in a vertical direction (Y).

2. (canceled)

3. The apparatus according to claim 1, wherein the deposition source is an evaporation source or a sputter source.

4. The apparatus according to claim 1, wherein the first active magnetic unit is an element selected from the group consisting of: an electromagnetic device; a solenoid; a coil; a superconducting magnet; and any combination thereof.

5. The apparatus according to claim 1, wherein the guiding structure is made of magnetic material.

6. The apparatus according to claim 1, further comprising a magnetic drive system configured for contactless transportation of the deposition source assembly in the source transportation direction along the guiding structure.

7. An apparatus for contactless levitation of a deposition source, comprising:
a deposition source assembly having a first rotation axis, wherein the deposition source assembly comprises:
a deposition source;
a first active magnetic unit arranged at a first side of the deposition source assembly; and
a second active magnetic unit arranged at a second side of the deposition source assembly;
a guiding structure including a passive magnetic unit; and
a controller configured for controlling the first active magnetic unit and the second active magnetic unit, wherein the first active magnetic unit and the second active magnetic unit are configured for magnetically levitating the deposition source assembly and for rotating the deposition source around the first rotation axis for alignment of the deposition source.

8. The apparatus according to claim 7, wherein the deposition source assembly further comprises a third active magnetic unit and a fourth active magnetic unit configured for magnetically levitating the deposition source assembly, wherein:
the third active magnetic unit is arranged at the first side of the deposition source assembly;
the fourth active magnetic unit is arranged at the second side of the deposition source assembly; and
the first active magnetic unit, the second active magnetic unit, the third active magnetic unit and the fourth active magnetic unit are configured for rotating the deposition source assembly around the first rotation axis and around a second rotation axis of the deposition source assembly for alignment of the deposition source.

9. The apparatus according to claim 8, wherein the first rotation axis is parallel to a substrate receiving area of the apparatus and the second rotation axis is perpendicular to the substrate receiving area.

10. The apparatus according to claim 1, wherein the apparatus further comprises:
a first passive magnetic unit configured for providing a first transversal force (TI);
a further active magnetic unit configured for providing a first opposing transversal force (01), wherein the first opposing transversal force is an adjustable force counteracting the first transversal force; and
a controller configured for controlling the further active magnet unit to provide for a transversal alignment of the deposition source.

11. A method for contactlessly aligning a deposition source, comprising:
generating an adjustable magnetic field with an active magnetic unit to levitate the deposition source; and
controlling the adjustable magnetic field with a controller to align the deposition source.

12. A method for contactlessly aligning a deposition source, comprising:
providing a first magnetic levitation force (FI) with a first active magnetic unit and a second magnetic levitation force (F2) with a second active magnetic unit to levitate the deposition source, wherein the first magnetic levitation force is spaced from the second magnetic levitation force; and
controlling at least one of the first magnetic levitation force and the second magnetic levitation force with a controller to align the deposition source.

13. The method according to claim 12, further comprising:
providing a third magnetic levitation force and a fourth magnetic levitation force to levitate the deposition source, wherein the third magnetic levitation force is spaced from the fourth magnetic levitation force, wherein the first magnetic levitation force, the second magnetic levitation force, the third magnetic levitation force and the fourth magnetic levitation force are configured to rotate the deposition source with respect to a first rotation axis and with respect to a second rotation axis; and
controlling at least one of the first magnetic levitation force, the second magnetic levitation force, the third magnetic levitation force and the fourth magnetic levitation force to align the deposition source.

14. The method according to claim 11, further comprising:
providing a first transversal force (TI) acting on the deposition source, wherein the first transversal force is provided using a first passive magnetic unit;
providing a first opposing transversal force (01) acting on the deposition source, wherein the first opposing transversal force is an adjustable magnetic force counteracting the first transversal force; and
controlling the first opposing transversal force to provide for a transversal alignment of the deposition source.

15. The method according to claim 11, wherein the aligning of the deposition source is performed when the deposition source is in a first position, the method further comprising:
transporting the deposition source from the first position to a second position; and contactlessly aligning the deposition source when the deposition source is in the second position.

16. The method according to claim 11, wherein the aligning of the deposition source is performed relative to a first substrate while the deposition source moves past a first substrate.

17. The apparatus according to claim 1, wherein the guiding structure is made of ferromagnetic material.

18. The apparatus according to claim 6, wherein the magnetic drive system comprises a passive magnetic unit at the guiding structure and an active magnetic unit in or at the deposition source assembly.

19. The apparatus according to claim 18, wherein the controller is connected to the drive system to control the speed of the deposition source assembly.

20. The apparatus according to claim 18, wherein the passive magnetic unit comprises a plurality of permanent magnets with varying pole orientation.

21. The method according to claim 11, wherein the aligning of the deposition source is performed relative to a first substrate while the deposition sources moves past a first substrate in a first position and relative to a second substrate while the deposition sources moves past a second substrate in a second position different from the first position.
